(19) United States
(12) Patent Application Publication
(10) Pub. No.: US 2026/0161841 A1
(43) Pub. Date: Jun. 11, 2026

(54) MANUFACTURING TOLERANCES FOR A MASTER GEAR

(71) Applicant: Klingelnberg AG, Zürich (CH)

(72) Inventor: Alexander Landvogt, Rockenberg (DE)

(21) Appl. No.: 19/400,418

(22) Filed: Nov. 25, 2025

(30) Foreign Application Priority Data
Dec. 9, 2024 (EP) 24218477.8

(51) Int. Cl. G06F 30/17; G01B 21/16; G06F 30/27

(52) U.S. Cl. CPC G06F 30/17; G06F 30/27; G01B 21/16

(57) ABSTRACT

A method, including defining manufacturing tolerances as permissible deviations from a predetermined target geometry of a master gear, which is a master gear for a rolling test, wherein, to define the manufacturing tolerances, a worst-case assessment for geometry deviation parameters of a gearing of the master gear and/or associated mating gear is performed by computer-implemented tooth contact analysis whereby calculated deviation of at least one value of a test characteristic of the rolling test from the geometry deviation parameters is smaller than a specified limit value. The computer-implemented tooth contact analysis includes an AI model that has been trained using training data. The training data include values of test characteristics of a rolling test of gearings exhibiting geometry deviation parameters that have been determined in simulation-based tooth contact analyses and/or test bench-based analyses. Also included are geometries of the gearings exhibiting geometric deviation parameters associated with these values.

### CROSS-REFERENCE TO RELATED APPLICATIONS

This application claims the benefit of European patent application no. 24218477.8, filed on 9 Dec. 2024, the disclosure of which is incorporated herein by reference in its entirety.

### TECHNICAL FIELD

The present disclosure relates to a method for defining manufacturing tolerances for a target geometry of a master gear, which is a master gear for a rolling test. The disclosure also relates to a device for defining manufacturing tolerances for a target geometry of a master gear.

### BACKGROUND

The rolling test is used, for example, to test the rotational error and noise behavior of running gears. A distinction is made between single-flank rolling tests and double-flank rolling tests.

The basic principle of single-flank rolling test is based on a master gear, i.e., a virtually flawless gear, and the gear to be tested rolling at a fixed center distance. A braked axle ensures that only one flank, i.e., the left or right flank, is in contact during rolling. Errors in the rotational transmission are measured by angle measuring systems, rotational acceleration sensors, and vibration sensors.

For the double flank rolling test, the gear to be tested and the master gear have a dynamic center distance between them, wherein the gear to be tested and the master gear are in double flank contact, i.e., the left and right flanks are in contact at the same time. The master gear is held on a linearly movable test carriage. The gear under test is driven and the master gear is pressed into double flank contact with a defined force. Geometric errors or damage to the teeth of the gear under test cause the test carriage with the master gear to shift, and this shift is recorded and evaluated.

The quality of the measurement results of the rolling test depends crucially on the fact that the master gear only exhibits manufacturing deviations of such a magnitude that they do not lead to any significant change in the measurement results of the rolling test, especially in the case of single-flank rolling test, i.e., the rotational error measurement. In other words, if the same gear tooth profile is tested against two identical master gears, the rolling test should produce the same test result. Identical master gears are identical in terms of their target geometry and differ only in terms of manufacturing deviations within the specified manufacturing tolerances.

To ensure that a manufactured master gear is suitable for rolling tests and for measuring rotational errors, these manufacturing tolerances for the master gear must be defined in such a way that the influence of manufacturing deviations of the master gear on the measurement result is kept to a minimum or within a specified range.

To define these manufacturing tolerances, a worst-case assessment of manufacturing tolerances can be performed. This worst-case assessment can be used to demonstrate that, for specified manufacturing tolerances, in the worst case, e.g., the measured rotational error does not deviate by more than a specified percentage from a simulation-based rotational error calculated using tooth contact analysis for a deviation-free master gear, provided that these manufacturing tolerances are adhered to.

In other words, for the worst-case assessment, all combinations of manufacturing deviations within a specified tolerance range can be calculated using tooth contact analysis, wherein the worst-case scenario is the one in which the calculated rotational error deviates most significantly from a target rotational error, wherein the target rotational error would result from a production-error-free gearing. If it is determined that even for this worst-case scenario, an acceptable influence of the manufacturing deviations of the master gear on the results of the rolling test has been calculated, the specified manufacturing tolerances are suitable for use in the manufacture of the master gear.

For the worst-case assessment, various combinations of manufacturing deviations in the gearing of the master gear in different forms or gradations must therefore be calculated using tooth contact analysis, which lie within a specified tolerance range.

The term “worst-case assessment” means considering the worst possible case, i.e., in this case, the most unfavorable combination of manufacturing deviations of the master gear and/or the associated mating gear, which would subsequently have the greatest influence on the measurement result.

Using known methods of simulation-based tooth contact analysis, a great deal of computing time is required to perform such a worst-case assessment. For example, for five geometry deviation parameters each for the master gear and the associated mating gear, and with a gradation of the geometry deviation parameters in three steps to +1/0/−1 μm, this results in a number of variants of 3exp10=59049 variants. For a gradation of the geometry deviation parameters in five steps to +2/+1/0/−1/−2 μm, this already results in a number of variants of 5exp10=9765625. With a computing time of approximately 75 seconds per simulation-based tooth contact analysis, the computing time for the examples mentioned is 51 days and 8477 days, respectively. Such a calculation of simulation-based tooth contact analyses is therefore not suitable in operational practice for determining manufacturing tolerances within the scope of designing a master gear.

The determination of manufacturing tolerances in the context of designing a master gear is therefore currently based on empirical values, and a large number of master gears are manufactured using a trial-and-error process until a suitable master gear has been produced. It goes without saying that this procedure is time-consuming and may result in a large number of defective parts being produced.

### SUMMARY

Against this background, the technical problem underlying the present disclosure is to provide an improved and, in particular, more efficient method for defining manufacturing tolerances for a master gear. Furthermore, a device for defining manufacturing tolerances for a master gear is to be provided.

The technical problem described above is solved in each case by the features of the independent claims. Further designs are apparent from the dependent claims and the following description.

According to a first aspect, the disclosure relates to a method comprising the following steps: defining manufacturing tolerances as permissible deviations from a specified target geometry of a master gear, which is a master gear for a rolling test, wherein, in order to define the manufacturing tolerances, a worst-case assessment for two or more geometry deviation parameters of a gearing of the master gear and/or an associated mating gear is performed by means of computer-implemented tooth contact analysis in such a way that a calculated deviation of at least one value of a test characteristic of the rolling test resulting from the geometry deviation parameters is smaller than a specified limit value, wherein the computer-implemented tooth contact analysis comprises an Al model that has been trained using training data, wherein the training data comprise values of one or more test characteristics of a rolling test of gearings exhibiting geometry deviation parameters, wherein these values have been determined in simulation-based tooth contact analyses and/or test bench-based analyses, and wherein the training data comprise the geometries of the gearings exhibiting the geometry deviation parameters associated with these values.

Geometry deviation parameters of the gearing of the master gear and/or the associated mating gear, which are taken into account in the worst-case assessment or which are specified for the worst-case assessment, are selected, for example, from: individual pitch deviation; total pitch deviation; concentricity deviation; tooth thickness deviation; profile angle deviation; profile shape deviation; total profile deviation; flank line angle deviation; flank line shape deviation; total flank line deviation; tip relief; root relief; profile angle modification; profile crowning; end relief; flank line angle modification; lead crowning; profile twist; flank line twist.

The assigned mating gear can represent the gearing to be tested within the framework of computer-implemented tooth contact analysis. The worst-case assessment takes into account not only the influence of the geometry deviation parameters of the master gear when rolling with a perfect mating gear or test specimen, but also gives preference to the influence of the interaction of various geometry deviation parameters of the master gear and the mating gear.

In particular, geometry deviation parameters of the mating gear are specified within the tolerance range of the gearing to be tested in practice.

Test characteristics of the rolling test that are taken into account in the worst-case assessment or that are specified for the worst-case assessment are selected from, for example: rotational error, center distance, concentricity, tooth-to-tooth runout, rolling deviation, dimension over balls, concentricity error, tooth-to-tooth amplitude (long-wave and short-wave), maximum rolling deviation, transmission error and dynamic backlash, noise behavior, surface defects.

When referring to a calculated deviation of at least one value of a test characteristic of the rolling test resulting from the geometric deviation parameters, this deviation is calculated in comparison to a defect-free master gear and a defect-free mating gear. This means that values of a test characteristic of the rolling test for a defect-free master gear and a defect-free mating gear, which correspond exactly to their specified target geometry, are used as a reference to determine the influence of the geometry deviation parameters of a non-defect-free master gear on the result of the rolling test.

The use of the AI model makes it possible to reduce the computing time required to determine manufacturing tolerances many times over, as time-consuming, simulation-based tooth contact analyses are no longer necessary.

Input data for the AI model includes, for example, the target geometry or gear data of the master gear, such as module, number of teeth, helix angle, modifications, etc., as well as two or more geometry deviation parameters from this target geometry, each in specified increments.

Input data for the AI model includes, for example, the target geometry or gear data of the mating gear, such as module, number of teeth, helix angle, modifications, etc., as well as two or more geometry deviation parameters from this target geometry, each in specified increments.

The output data of the AI model includes, for example, expected deviations for one or more test characteristics of the rolling test resulting from these geometric deviation parameters. The advantage of using the AI model is that the computing time for the selected combinations and gradations of the geometric deviation parameters can be significantly reduced.

It may be provided that a specific AI model trained only for this test characteristic is provided for a respective test characteristic of the rolling test. Therefore, several AI models may be provided, each of which has been trained with regard to different test characteristics of the rolling test.

For example, an AI model may be provided that is specifically designed to determine an expected rotational error resulting from two or more geometry deviation parameters of the master gear and/or the mating gear. This applies equally to the other test characteristics of the rolling test mentioned above.

The worst-case assessment may involve performing several computer-implemented tooth contact analyses for different combinations and characteristics of geometry deviation parameters. This means that the number of test points to be considered or calculated is not reduced by using the AI model, but only the computing time per test point.

It may be provided that at least two characteristics are specified for at least one of the geometric deviation parameters or for each of the geometric deviation parameters, in particular up to ten characteristics are specified, and further in particular up to five characteristics are specified.

A respective characteristic for a respective geometric deviation parameter can be specified as a deviation in a unit of measurement relative to the target geometry. In particular, a respective characteristic can be specified as a gradation within a predetermined value range of the respective geometric deviation parameter.

The AI model can be selected from the following model types or based on the following calculation methods, wherein, as already mentioned, several AI models can be part of the computer-implemented tooth contact analysis: neural network, in particular deep or shallow neural network, radial basis function, kriging, relevance vector regression, random forest regression, Taylor polynomials, optimal response surface modeling, Akaike information criterion.

It may be provided that the target geometry is designed before manufacturing tolerances are defined.

Furthermore, it may be provided that, after defining the manufacturing tolerances, the master gear is manufactured in compliance with the defined manufacturing tolerances.

According to a second aspect, the disclosure relates to a device with a software program product designed to execute a method according to the disclosure.

### BRIEF DESCRIPTION OF THE DRAWINGS

The disclosure is explained in more detail below with reference to a drawing illustrating an exemplary embodiment. The following figures show schematically:

FIG. 1 shows a master gear;

FIG. 2 shows method steps of a method according to the disclosure; and

FIG. 3 shows a device for carrying out the method according to the disclosure as shown in FIG. 1.

### DETAILED DESCRIPTION OF THE DRAWINGS

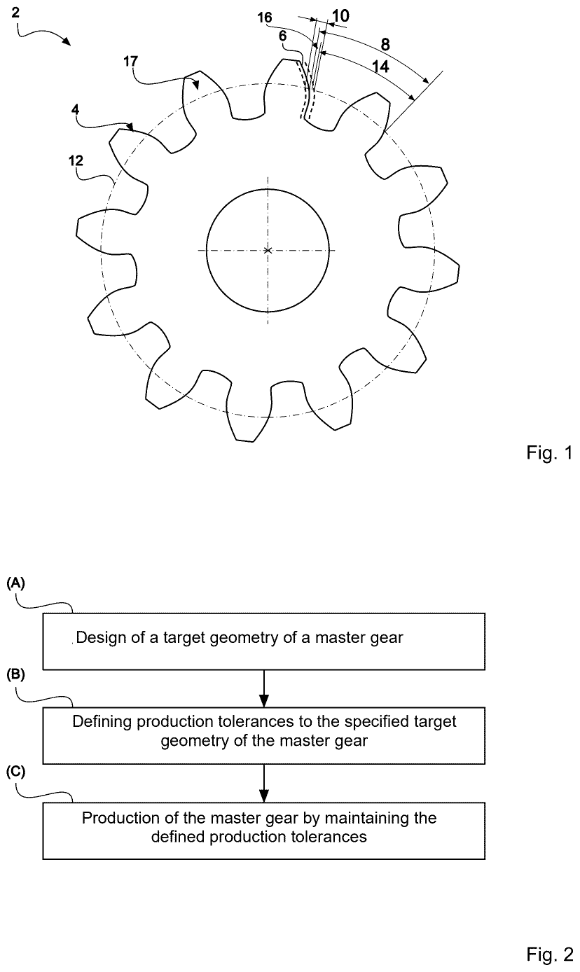

FIG. 1 shows, by way of example and schematically, a master gear 2 with a target geometry 4, on the basis of which a method according to the disclosure is explained in more detail. FIG. 2 shows method steps of the method according to the disclosure.

The method comprises the following method steps: (A) Designing the target geometry 4 of the master gear 2; (B) Defining manufacturing tolerances for the specified target geometry 4 of the master gear 2; (C) Manufacturing the master gear 2 in compliance with the defined manufacturing tolerances.

FIG. 1 shows schematically and by way of example a specified target pitch 8 as a gearing parameter and thus as part of the target geometry 4 on the pitch circle 12. For this target pitch 8, a tolerance range 10 is to be defined, for example, as part of the manufacturing tolerances to be complied with for the master gear 2. Tooth flanks 6 of the master gear 2 must therefore be within the tolerance range 10 after the manufacture of the master gear 2 in question. A deviation 16 of an actual tooth pitch 14 from the specified target pitch 8 can be referred to as a pitch error.

Such a pitch error has been presented here solely for a better understanding of the present disclosure as an example of a geometric deviation parameter of the master gear 2. For the worst-case assessment described in more detail below, several geometric deviation parameters can be specified, e.g., selected from: individual pitch deviation; total pitch deviation; concentricity deviation; tooth thickness deviation; profile angle deviation; profile shape deviation; total profile deviation; flank line angle deviation; flank line shape deviation; total flank line deviation; tip relief; root relief; profile angle modification; profile crowning; end relief; flank line angle modification; lead crowning; profile twist; flank line twist. These geometric deviation parameters are well known in gear technology and are therefore not described in detail here.

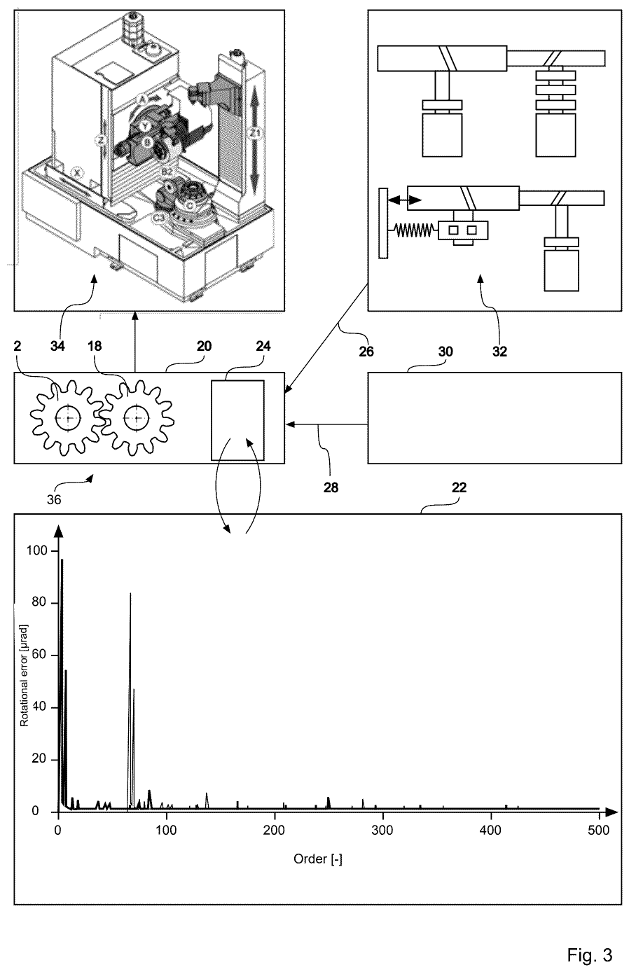

To define the manufacturing tolerances, a worst-case assessment is performed for two or more geometric deviation parameters of a gearing 17 of the master gear 2 and/or an associated mating gear 18 (FIG. 3) is performed by means of computer-implemented tooth contact analysis 20 in such a way that a calculated deviation of at least one value of a test characteristic of the rolling test, which results from the geometric deviation parameters, is smaller than a specified limit value. FIG. 2 shows an example of a rotational error as an order spectrum 22, wherein such a limit value can be specified for each order, or a maximum permissible rotational error resulting from the geometric deviation parameters can be specified as a limit value for the rotational error.

In addition to the rotational error, other test characteristics of the rolling test can also be used, such as: center distance, concentricity, tooth-to-tooth runout, rolling deviation, dimension over balls, concentricity error, tooth-to-tooth amplitude (long-wave and short-wave), maximum rolling deviation, transmission error and dynamic backlash, noise behavior, surface defects.

The computer-implemented tooth contact analysis 20 features an AI model 24.

The AI model 24 has been trained using training data 26, 28, wherein the training data 26, 28 comprise values of one or more test characteristics of a rolling test of gearings exhibiting geometric deviation parameters, wherein these values have been determined in simulation-based tooth contact analyses 30 and/or test bench-based using rolling test benches 32, and wherein the training data 26, 28 comprise the geometries of the gearings exhibiting geometry deviation parameters associated with these values.

The worst-case assessment involves performing several computer-implemented tooth contact analyses 20 for different combinations and characteristics of geometry deviation parameters.

At least two characteristics are specified for each of the geometry deviation parameters. A respective characteristic for a respective geometry deviation parameter is specified as a deviation in a unit of measurement relative to the target geometry.

In the present example, the worst case for each of five geometry deviation parameters for the master gear 2 and the counter gear 18 is calculated, with the geometry deviation parameters graded in three steps to +1/0/−1 μm, i.e., a number of variants of 3exp10=59049 variants, each of which is evaluated using the Al model 24.

The method according to the disclosure can be carried out by means of a device such as a computer 36 with a software program product set up to execute the method according to the disclosure.

Once the manufacturing tolerances have been determined, the master gear 2 can be manufactured using a gear cutting machine 34.

1. A method including, the following steps:
defining manufacturing tolerances as permissible deviations from a predetermined target geometry of a master gear, which is a master gear for a rolling test,
wherein, in order to define the manufacturing tolerances, a worst-case assessment for two or more geometric deviation parameters of a gearing of the master gear and/or an associated mating gear is performed by means of computer-implemented tooth contact analysis whereby
calculated deviation of at least one value of a test characteristic of the rolling test resulting from the geometric deviation parameters is smaller than a specified limit value,
wherein the computer-implemented tooth contact analysis comprises an AI model that has been trained using training data, wherein the training data comprises values of one or more test characteristics of a rolling test of gearings exhibiting geometry deviation parameters, wherein these values have been determined in simulation-based tooth contact analyses and/or test bench-based analyses, and wherein the training data comprise the geometries of the gearings exhibiting the geometric deviation parameters associated with these values.

2. The method according to claim 1,
wherein the worst-case assessment comprises performing a plurality of computer-implemented tooth contact analyses for different combinations and characteristics of geometry deviation parameters.

3. The method according to claim 2,
wherein at least two characteristics are specified for at least one of the geometry deviation parameters or for each of the geometry deviation parameters, in particular up to ten characteristics are specified.

4. The method according to claim 3,
wherein a respective characteristic value for a respective geometric deviation parameter is specified as a deviation in a unit of measurement relative to the target geometry, in particular that a respective characteristic value is specified as a gradation within a predetermined value range of the respective geometric deviation parameter.

5. The method according to claim 1,
wherein the AI model is selected from the following model types and/or is based on the following calculation methods:
neural network, in particular deep or shallow neural network, radial basis function, kriging, relevance vector regression, random forest regression, Taylor polynomials, optimal response surface modeling, Akaike information criterion.

6. The method according to claim 1,
wherein before defining manufacturing tolerances, a design of the target geometry is carried out; and/or
after defining the manufacturing tolerances, the master gear is manufactured in compliance with the defined manufacturing tolerances.

7. A device comprising: a software program product, set up to execute the method according to claim 1.
